(19) United States
(12) Patent Application Publication
(10) Pub. No.: US 2004/0213415 A1
(43) Pub. Date: Oct. 28, 2004

(54) Determining reverberation time

(76) Inventors: Ratnam Rama, Champaign, IL (US); Albert S. Feng, Champaign, IL (US); Douglas L. Jones, Champaign, IL (US); Charissa R. Lansing, Champaign, IL (US); William D. O'Brien, Champaign, IL (US)

Correspondence Address: Woodard, Emhardt, Moriarty, McNett & Henry LLP, Bank One Center/Tower, Suite 3700, 111 Monument Circle, Indianapolis, IN, 46204-5137, US

(21) Appl. No.: 10/807,885

(22) Filed: Mar. 24, 2004

Related U.S. Application Data
(60) Provisional application No. 60/466,133, filed on Apr. 28, 2003.

(51) Int. Cl. H04R 5/00; H03G 3/00

(52) U.S. Cl. 381/63; 381/56

(57) ABSTRACT

Included in the embodiments of the present invention is a technique to detect sound with a sensor to generate a corresponding sound signal and iteratively determine two or more values with a maximum likelihood function for evaluation of reverberation time. One of these values corresponds to a time constant parameter, and another of these values corresponds to a diffusive power parameter. An estimate representative of the reverberation time is further provided as a function of an order-statistics filter.

### CROSS-REFERENCE TO RELATED APPLICATIONS

The present application claims the benefit of U.S. Provisional Patent Application No. 60/466,133 filed 28 Apr. 2003, which is hereby incorporated by reference in its entirety.

### GOVERNMENT RIGHTS

This invention was made with Government support under Contract Number R21-DC-04840 awarded by the National Institute of Health (NIH). The Government has certain rights in the invention.

### BACKGROUND

The estimation of room reverberation time (RT) has long been of interest to engineers and acousticians. The RT of a room specifies the duration for which a sound persists after it has been switched off, which is typically due to multiple reflections of sound from the various surfaces within the room. Historically, RT has been referred to as the T₆₀ time—the time taken for sound to decay to 60 dB below its initial value at cessation.

Reverberation often results in temporal and spectral smearing of the sound pattern, thus distorting both the envelope and fine structure of the received sound. Consequently, the RT of a room provides a measure of the listening quality of the room, and can be of particular interest in evaluating speech perception. Generally, it has been noted that speech intelligibility reduces as RT increases, often because masking occurs within and across phonemes. The effect of reverberation is most noticeable when microphone-recorded speech is played back via headphones. Previously unnoticed distortions in the sound pattern are then often clearly discerned even by normal listeners—highlighting the echo suppression and dereverberation capabilities of the normal auditory system when the ears receive sounds directly. Accordingly, for hearing impaired listeners, the reception of reverberant signals via a hearing aid microphone frequently exacerbates the problem of listening in challenging environments. Thus, the ability to account for the degrading effects of reverberant environments is of significant interest. The determination of RT is often useful in this endeavor.

In the early 20th century, Sabine provided an empirical formula for the explicit determination of RT based on the geometry of the environment (volume and surface area) and the absorptive characteristics of its surfaces (See, Sabine, W. C., Collected Papers on Acoustics (Harvard University Press, Cambridge, Mass., 1922)). Since then, Sabine's reverberation-time equation has been extensively modified and its accuracy improved to the extent that it finds use in a number of commercial software packages for the acoustic design of interiors. Formulae for calculation of RT are used in anechoic chamber measurements, design of concert halls, classrooms, and other acoustic spaces where the quality of the received sound is of interest and/or it is desired to control the extent of reverberation. Because both the geometry and the absorptive characteristics need to be determined for these formulae, other approaches are considered when such information is unavailable or impractical to obtain.

For example, RT can be determined from controlled recordings of certain excitation sounds radiated in the enclosure of interest based on sound decay curves. In the Interrupted Noise Method (ISO 3382, 1997), a burst of broad- or narrow-band noise is radiated into the test enclosure. When the sound field attains steady state, the noise source is switched off and the decay curve is recorded. RT is estimated from the slope of the decay curve. However, because of fluctuations in the excitation noise signal, the decay curve will often differ from trial-to-trial, and so RTs from a large number of decay curves are typically averaged to obtain a reliable estimate. To overcome this drawback, Schroeder developed the Integrated Impulse Response Method where the excitation signal is a brief pulse, either broad- or narrow-band (See, Schroeder, M. R., “New Method for Measuring Reverberation Time,” J. Acoust. Soc. Amer., vol. 37, pp. 404-412, (1965)). In response to this brief pulse input, the enclosure output is the impulse response of the enclosure in the specified frequency band. Schroeder showed that the impulse response of the enclosure is related via a certain integral expression to the ensemble average of the decay curve obtained using the interrupted noise method, and so repeated trials were unnecessary. In practice, a suitable excitation signal must be available with sufficient power to provide at least a 35 dB decay range before the noise floor is encountered (see ISO 3382, 1997, for further specifications).

Unfortunately, Schroeder's approach is limited to situations where a suitable, known excitation signal is available. There remains a need for a technique to determine RT when the room geometry and absorptive characteristics are unknown, or when a controlled test sound cannot be employed. Further, for certain applications, it would be particularly desirable to have such a “blind” RT evaluation technique that works with speech.

Thus, there is an ongoing demand for further contributions in this area of technology.

### SUMMARY

One embodiment of the present invention includes a unique technique for evaluating reverberation. Other embodiments include unique processes, methods, systems, devices, and apparatus to determine reverberation time of a room.

A further embodiment includes a sensor for detecting sound and a processing subsystem. This processing subsystem receives sound-representative signals from the sensor to determine reverberation time of an unknown acoustic environment by processing these signals with a maximum likelihood estimator. In one form, processing further includes applying an order-statistics filter.

Another embodiment includes means for processing a number of sequences of observed sound data to provide a corresponding number of reverberation time parameter estimations with the parameter estimator. The sequences each correspond to one of a number of different time windows. This embodiment further includes means for filtering the estimations with an order-statistics filter to provide the reverberation time estimate.

In yet a further embodiment of the present invention, a system includes a sensor and a processor. The processor is responsive to signals from the sensor to evaluate reverberation by estimating one or more reverberation characteristics in accordance with a maximum likelihood function and applying an order-statistics filter.

In still a further embodiment, a memory device includes instructions executable by a processor to evaluate reverberation based on sound-representative signals from a sensor. The instructions define a routine to iteratively estimate one or more reverberation characteristics based on a maximum likelihood function and order-statistics filter. In one form, the memory device is removable and is of a disk, cartridge, or tape type.

Another embodiment of the present invention is directed to: detecting sound with a sensor to generate a corresponding sensor signal; generating data with the sensor signal in accordance with a maximum likelihood estimator; and filtering data with an order-statistics filter to provide an estimate of reverberation time. In one form, processing is performed within a single wideband channel spanning a frequency range of interest. In another form, processing is performed with respect to each of a number of narrowband channels; where the narrowband channels each correspond to a different acoustic signal frequency range. For this form, the estimate can be determined by combining estimation results for each of the channels.

Yet another embodiment of the present invention includes iteratively determining at least two values corresponding to a maximum likelihood function to evaluate one or more reverberation characteristics of an acoustic environment. In one form, one of the values corresponds to a time-constant parameter and/or another of the values corresponds to a diffusive power parameter of the reverberation. The evaluation can be completely or partially blind. In one partially blind approach, a neural network is included and trained to provide the reverberation characteristics of a selected room, outside region, or other acoustic environment based on the maximum likelihood evaluation. In addition, various filtering and windowing operations can be performed to further evaluate reverberation, such as applying an order-statistic filter to estimates from the maximum likelihood evaluation, processing sound data over one or more selected frequency bands, and/or adaptively changing processing window lengths.

In still another embodiment, a reverberation evaluation system, method, apparatus, or device of the present invention is provided with a hearing aid or other hearing assistance device, a hands-free telephony arrangement, a speech recognition arrangement, a telepresence/teleconference configuration, and/or sound level evaluation equipment. As used herein, “hearing assistance device” broadly includes any type of hearing aid, any type of sensory-based hearing prosthetic, a cochlear implant, an implantable hearing device, a vibrotactile or electrotactile hearing device, and/or any type of hearing enhancement, surveillance, or listening device whether for a hearing-impaired listener or a listener with normal hearing, just to name a few examples.

A further embodiment includes: preparing a number of observed sound data sequences each representative of sound over one of the number of different time periods, determining each of a number of estimations as a function of a different one of the sequences in accordance with a parameter estimator, and selecting one of the estimations to provide a reverberation time. In one form, the parameter estimator is based on a maximum likelihood function. Alternatively or additionally, the selection of one of the estimations is provided through order-statistics filtering.

Still another embodiment includes: preparing a number of observed sound data sequences each corresponding to sound over a different one of a number of time windows, determining a number of reverberation time parameter estimations that each are calculated as a function of one of the sequences in accordance with a parameter estimator, and filtering the estimations. In one particular form, this filtering is performed with an order-statistics filter and the parameter estimator is of a maximum likelihood type.

A system according to another embodiment of the present invention includes a sensor for detecting sound and a processing subsystem. The subsystem receives sound-representative signals from the sensor to determine a reverberation time estimate of an unknown acoustic environment by processing the signals with a parameter estimator and order-statistics filter.

Another embodiment of the present invention includes logic executable by one or more processors to evaluate data corresponding to a number of sequences of sound samples. The sequences each represent sound over a different time period. The logic is also operable to determine a number of reverberation time parameter estimations each as a function of a different one of the sequences in accordance with a parameter estimator. This logic is also configured to filter the estimations to provide a selected reverberation time estimate. In one form, the logic includes a number of software instructions stored on a computer-readable memory. In another form, the logic is encoded in one or more signals carried by one or more parts of a computer network.

Accordingly, one object of the present invention is to provide a unique technique to evaluate reverberation.

Another object is to provide a unique system, process, method, device, or apparatus to evaluate reverberation time of a designated room or space.

Other objects, embodiments, forms, features, advantages, aspects, and benefits of the present invention shall become apparent from the detailed description and drawings included herein.

### BRIEF DESCRIPTION OF THE DRAWING

FIG. 1 is a schematic view of a reverberation time estimation system.

FIGS. 2 and 3 are flowcharts illustrating a procedure for estimating reverberation time with the system of FIG. 1.

FIG. 4 is a comparative illustration of four plots depicting certain aspects of reverberation modeling.

FIG. 5 is a comparative illustration of four plots depicting certain aspects of maximum likelihood estimation.

FIG. 6 is a schematic view of an arrangement of RT estimate applications.

FIGS. 7-14 are plots of results from various experimental examples.

### DETAILED DESCRIPTION

While the present invention can take many different forms, for the purpose of promoting an understanding of the principles of the invention, reference will now be made to the embodiments illustrated in the drawings and specific language will be used to describe the same. It will nevertheless be understood that no limitation of the scope of the invention is thereby intended. Any alterations and further modifications of the described embodiments, and any further applications of the principles of the invention as described herein are contemplated as would normally occur to one skilled in the art to which the invention relates.

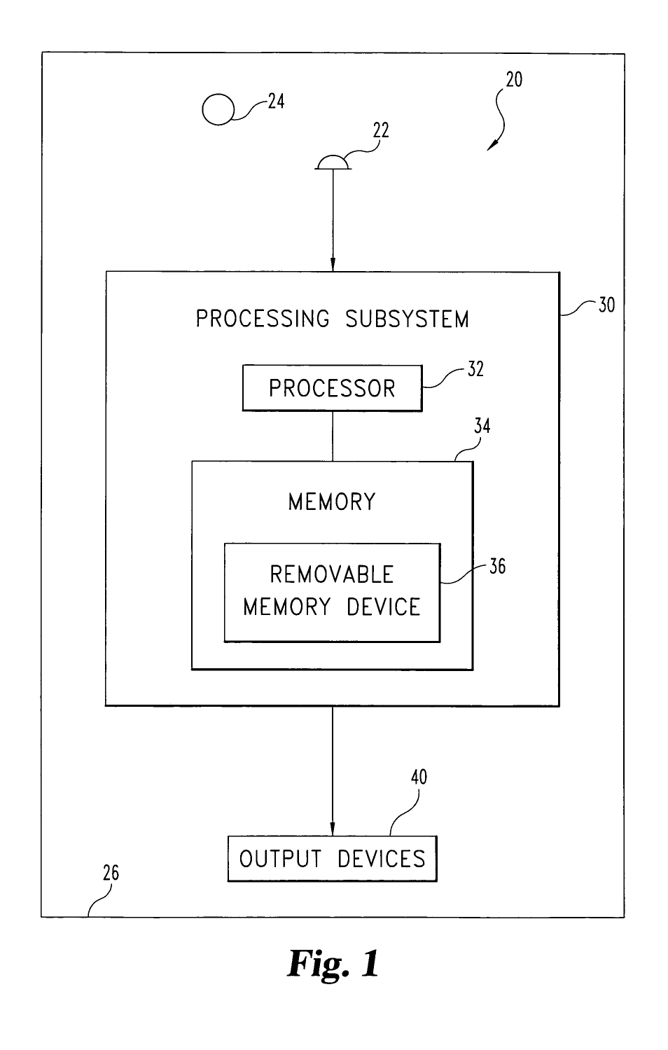

FIG. 1 illustrates system 20 of one embodiment of the present invention. System 20 is configured to detect sound with sensor 22 emanating from one or more acoustic sources 24 in room 26. Sensor 22 generates a corresponding sensor signal representative of the detected sound. For the example illustrated, only one sensor 22 is shown; however, more than one sensor may be utilized. Sensor 22 can be in the form of an omnidirectional dynamic microphone or a different type of microphone or sensor type as would occur to one skilled in the art. Sources 24 can be actively controlled and/or passive in nature. Indeed, in accordance with the teachings of the present invention, reverberation of an acoustic environment can be evaluated based only on the processing of sensor signals representative of uncontrolled, passive sound emanating from such environment.

System 20 further includes processing subsystem 30. Subsystem 30 includes at least one processor 32 and memory 34. Memory 34 includes removable memory device 36. Sensor 22 is operatively coupled to processing subsystem 30 to process signals received therefrom. Processing subsystem 30 is operable to provide an output signal representative of acoustic excitation detected with sensor 22 that may be modified in accordance with processing routines and/or parameters of subsystem 30. This output signal is provided to one or more output devices 40. In FIG. 1, the one or more output devices 40 are labeled in the plural, but are also intended to be representative of the presence of only a single output device. In one embodiment, at least one of output devices 40 presents an output to a user in the form of an audible or visual signal. In other embodiments, at least one of output devices 40 provides a different user/operator output and/or is in the form of other equipment that utilizes the output signal for further processing. In still other embodiments, one or more output devices 40 are absent (not shown).

Processor 32 is responsive to signals received from sensor 22. Processor 32 can be of an analog type, digital type, or a combination of these. Subsystem 30 can include appropriate signal conditioning/conversion to provide a sound-representative signal to processor 32 from sensor 22. Processor 32 may be a software or firmware programmable device, a state logic machine, or a combination of both programmable and dedicated hardware. Furthermore, processor 32 can be comprised of one or more components and/or can include one or more independently operable processing components. For a form with multiple independently operable processing components; distributed, pipelined, and/or parallel processing can be utilized as appropriate. In one embodiment, processor 32 is in the form of a digitally programmable signal processing semiconductor component that is highly integrated. In other embodiments, processor 32 may be of a general purpose type or other arrangement as would occur to those skilled in the art.

Likewise, memory 34 can be variously configured as would occur to those skilled in the art. Memory 34 can include one or more types of solid-state electronic memory, magnetic memory, or optical memory of the volatile and/or nonvolatile variety. Furthermore, memory 34 can be integral with one or more other components of processing subsystem 30 and/or comprised of one or more distinct components. For instance, memory 34 can be at least partially integrated with processor 32. Removable Memory Device (RMD) 36 is of a computer/processor accessible type that is portable, such that it can be used to transport data and/or operating instructions to/from subsystem 30. Device 36 can be of a floppy disk, cartridge, or tape form of removable electromagnetic recording media; an optical disk, such as a CD or DVD type; an electrically reprogrammable solid-state type of nonvolatile memory, and/or such different variety as would occur to those skilled in the art. In one embodiment, device 36 is utilized to load and/or store at least a portion of the operating logic for subsystem 30. This operating logic can be in the form of instructions carried by device 36 that are executed by processor 32 to perform one or more procedures, operations, and/or routines according to the present invention. In other embodiments, some or all of this operating logic is stored in another portion of memory 34, and/or is defined by dedicated logic of subsystem 30 and/or processor 32. In still other embodiments, device 36 is absent.

Processing subsystem 30 can include one or more signal conditioners/filters to filter and condition input signals and/or output signals; one or more format converters, such as Analog-to-Digital (A/D) and/or Digital-to-Analog (DAC) converter types; and/or one or more oscillators, control clocks, interfaces, limiters, power supplies, communication ports, or other types of components/devices as would occur to those skilled in the art to implement the present invention. In one embodiment, subsystem 30 is provided in the form of a single microelectronic device.

System 20 can be implemented in any of a number of various ways in different embodiments. By way of nonlimiting example, system 20 can be utilized in hearing assistance devices for the hearing impaired and/or for surveillance. In other embodiments, system 20 is utilized in speech recognition arrangements, hands-free telephony devices, remote telepresence or teleconferencing configurations, sound level evaluation equipment, or different applications as would occur to those skilled in the art. In all these embodiments, the evaluation of one or more reverberation characteristics of a subject acoustic environment, such as a room or outside region, is often desired to improve performance.

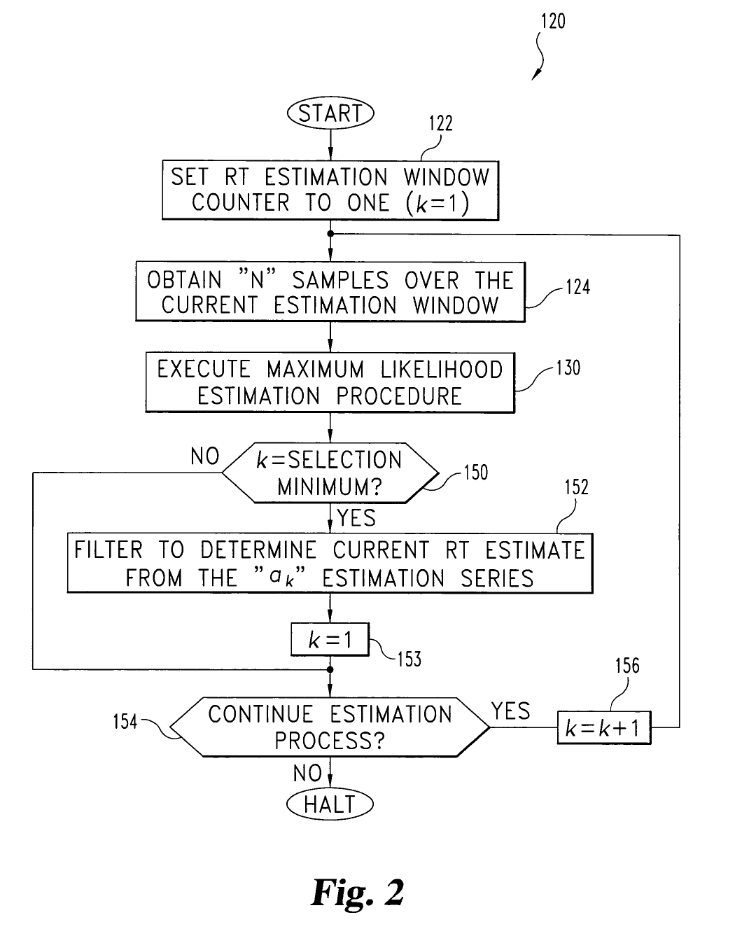

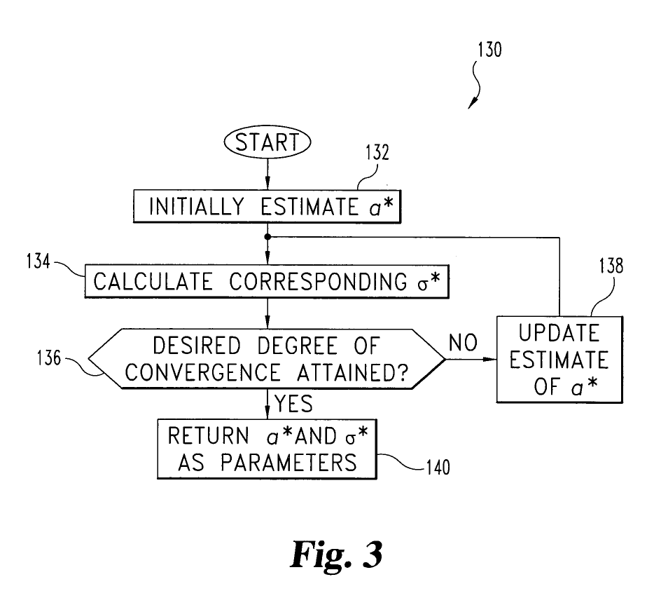

System 20, and the embodiments, variations, and forms described in connection with system 20, are but a few examples of arrangements that can be used to implement the reverberation evaluation techniques of the present invention. Among these techniques is an embodiment for the blind estimation of Reverberation Time (RT) based on passively detected and/or recorded sounds. This estimation is based on a predetermined noise decay curve model used to describe the reverberation characteristics of the acoustic environment. Sounds in this environment (speech, music, or other-pre-existing sounds) are continuously processed, and a running estimate of the reverberation time is generated using a parameter estimator. Estimates of RT are collected over a period of time and the most likely RT is selected using an order-statistics filter. Further details of RT estimation according to the present invention are provided in connection with the flowcharts of FIGS. 2 and 3 hereinafter.

However, before considering these details, further aspects regarding the measurement and modeling of sound decay are first described in relation to RT estimation. As previously explained, a commonly used measure of the reverberation time is the T₆₀ time, which is now a part of the ISO reverberation measurement procedure (ISO 3382, 1997). The T₆₀ time is the amount of time taken for the sound level to drop 60 dB below the sound level at the point of cessation of sound generation. In practice, a decaying sound often reaches the ambient noise floor before a 60 dB drop is reached. As a result, the decay rate is commonly estimated by a linear least-squares regression of the measured decay curve from a level 5 dB below the initial level to 35 dB (definition adopted from ISO 3382, 1997, p. 2). If a 30 dB decay range cannot be measured, then a 20 dB range can be used. The T₆₀ time is then extrapolated from the measured decay rate.

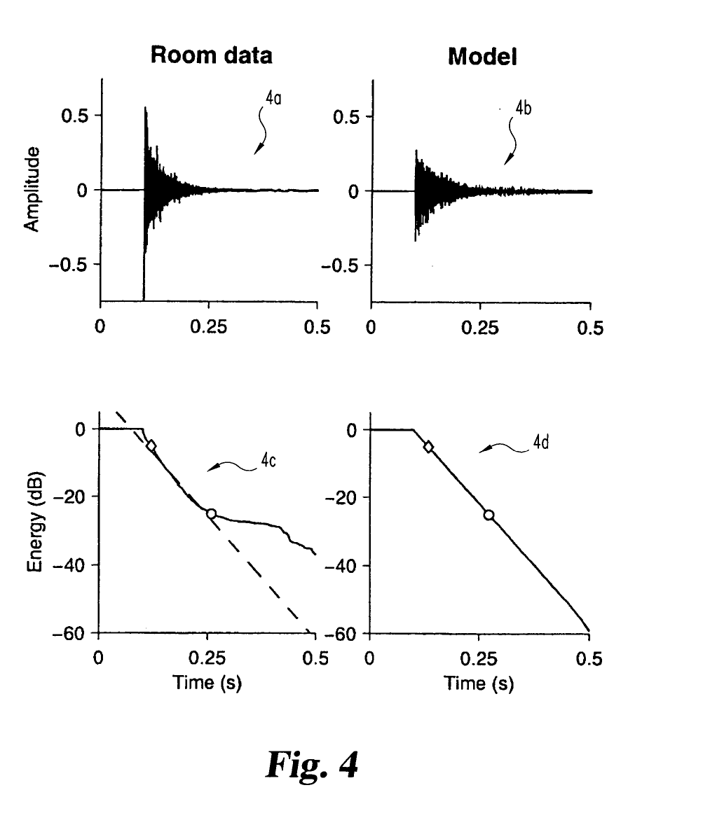

The recorded response of a room to an impulsive sound source (a hand-clap) is shown at a time of 0.1 second(s) after cessation in plot 4a of FIG. 4. As can be expected, there are strong early reflections followed by a decaying reverberant tail. The model of plot 4b excludes direct sound, matching the reverberant tail shown in plot 4a. This model is a Gaussian white noise process damped by a decaying exponential, parametrized by the noise power or and decay rate τ. If the early reflections are ignored, the decay rate of the tail can be estimated from the envelope. Plot 4c shows the measurement of T₆₀ for the data of plot 4a using the decay rate estimated from the −5 to −25 dB decay region, based on the backward integration procedure of Schroeder. In plot 4c, the slope of linear fit (dashed line) yields τ=59 ms (T₆₀=0.4 s). In plot 4d, The decay curve for the model of plot 4b as determined using this same procedure has a uniform slope following sound offset that captures the most significant part of decay (−5 dB to −25 dB).

A diffusive or reverberant tail of sounds in a room refers to the dense reflections that follow the early reflections. These dense reflections generally result from multiple reflections, and appear in random order, with successive reflections being damped to a greater degree if they occur later in time. When a burst of white noise is radiated into a test enclosure, the phase and amplitudes of the normal modes are random in the instant preceding the cessation of the sound. Consequently, the decaying output of the enclosure following sound cessation will also be random, even if repeated trials were conducted with the same source and receiver geometry. Traditionally, the late decay envelope has been modeled as an exponential with a single (deterministic) time-constant (hereafter referred to as decay rate); however, because the dense reflections are assumed to be uncorrelated, an alternative model considers the reverberant tail to be an exponentially damped uncorrelated noise sequence with Gaussian characteristics. This model does not include the direct sound or early reflections. The decaying sound y of the reverberant tail can be modeled as the combination of a fine structure x that is random process, and an envelope a that is deterministic; where x is a wide-band process subject to rapid fluctuations, and variations in a are over much longer time-scales.

Let the fine structure of the reverberant tail be denoted by a random sequence x(n), n≧0 of independent and identically random variables drawn from the normal distribution N(0, σ). For each n, define a deterministic sequence a(n)>0. The model for room decay then suggests that the observations y are specified by the sequence y(n)=a(n)x(n). Due to the time-varying term a(n), the y(n) are independent but not identically distributed, and their probability density function is N(0, σ a(n)). That is, the sequence a(n) modulates the instantaneous power of the fine structure. For purposes of estimating the decay rate, consider a finite sequence of observations, n=0, . . . , N−1; where N refers to the estimation interval, or estimation window length. For notational simplicity, denote the N-dimensional vectors of y and a by Y and A, respectively. Then the likelihood function of Y (the joint probability density), parameterized by A and σ, is given by expression (1) as follows:

$$L ( Y ; A , σ ) = \frac{1}{a ( 0 ) … a ( N - 1 )} {( \frac{1}{2 π {σ}^{2}} )}^{N / 2} exp ( - \frac{{\sum }_{n = 0}^{n = N - 1} {( y ( n ) / a ( n ) )}^{2}}{2 {σ}^{2}} ) \qquad ( 1 )$$

where a(0), . . . , a(N−1), and σ are the (N+1) unknown parameters to be estimated from the observation Y. Rather than estimating all (N+1) parameters, let a single decay rate τ describe the damping of the sound envelope during free decay. As a result, the sequence a(n) can be modeled as set forth in expression (2) as follows:

a(n)=exp(−n/τ). (2)

Thus, the N-dimensional parameter A can be replaced by a scalar parameter a that is expressible in terms of T and a single parameter a=exp(−1/τ), so that expression (3) results:

a(n)=aⁿ. (3)

Substituting expression (3) into expression (1) results in expression (4) as follows:

$$L ( Y ; a , σ ) = {( \frac{1}{2 π a ( N - 1 ) {σ}^{2}} )}^{N / 2} exp ( - \frac{{\sum }_{n = 0}^{n - 1} {a}^{- 2 n} {y ( n )}^{2}}{2 {σ}^{2}} ) \qquad ( 4 )$$

For a fixed observation window N and a sequence of observations y(n), the likelihood function is parameterized by the decay rate a and the diffusive power σ.

The model shown in plot 4b of FIG. 4 has parameters a and σ matched to the experimental hand-clap data shown in plot 4a at FIG. 4, except for the early reflections shown in plot 4a. The Schroeder decay curve for the model shown in plot 4d with a T₆₀ time of 0.4 is in agreement with the measured T₆₀. Given this agreement, the efficacy of Maximum Likelihood Estimation (MLE) characterization in terms of a and σ is established. Indeed, the parameters a and σ can be estimated using a maximum-likelihood approach. Taking the logarithm of expression (4), the following expression (5) of the log-likelihood function results:

$$ln L ( Y ; a , σ ) = - \frac{N ( N - 1 )}{2} ln ( a ) - \frac{N}{2} ln ( 2 π {σ}^{2} ) - \frac{1}{2 {σ}^{2}} {\sum }_{n = 0}^{N - 1} {a}^{- 2 n} {y ( n )}^{2} \qquad ( 5 )$$

To find the maximum of ln(L), the log-likelihood function of expression (5) is differentiated with respect to a to obtain the score function sₐ as set forth in expressions (6) and (7) that follow:

$$\begin{matrix}{s}_{a} ( a ; Y , σ ) = \frac{\partial ln L ( Y ; a , σ )}{\partial a} & ( 6 ) \\ = - \frac{N ( N - 1 )}{2 a} + \frac{1}{a {σ}^{2}} {\sum }_{n = 0}^{N - 1} n {a}^{- 2 n} {y ( n )}^{2} & ( 7 )\end{matrix}$$

The log-likelihood function achieves an extremum when ∂lnL(Y; a, σ)/∂a=0; that is, when the following expression (8) is valid:

$$- \frac{N ( N - 1 )}{2 a} + \frac{1}{a {σ}^{2}} {\sum }_{n = 0}^{N - 1} n {a}^{- 2 n} {y ( n )}^{2} = 0 \qquad ( 8 )$$

The zero of the score function provides a best estimate in the sense that E[sₐ]=0. Denoting the zero of the score function sₐ, and satisfying Expression (8), by a*, it can be shown that the estimate a* maximizes the log-likelihood function, given that expression (8a):

$$\frac{{\partial }^{2} ln L ( Y ; a , σ )}{\partial {a}^{2}} {\vert}_{a = {a}^{*}} < 0 , \qquad ( 8 a )$$

The diffusive power of the reverberant tail, or variance σ², can be estimated in a similar manner. Differentiating the log-likelihood function of expression (5) with respect to σ, expressions (9) and (10) result as follows:

$$\begin{matrix}{s}_{σ} ( σ ; Y , a ) = \frac{\partial ln L ( Y ; a , σ )}{\partial σ} , & ( 9 ) \\ = - \frac{N}{σ} + \frac{1}{ {σ}^{3}} {\sum }_{n = 0}^{N - 1} {a}^{- 2 n} {y ( n )}^{2} & ( 10 )\end{matrix}$$

An extremum is achieved according to expression (11) that follows:

$${σ}^{2} = \frac{1}{N} {\sum }_{n = 0}^{N - 1} {a}^{- 2 n} {y ( n )}^{2 n} \qquad ( 11 )$$

As before, it can be shown that E[s_{σ}]=0. Denoting the zero of the score function s_{σ}, and satisfying expression (11), by σ*, it can be shown that the estimate σ* maximizes the log-likelihood function, according to the second derivative expressed in (11a) as follows:

$$\frac{{\partial }^{2} ln L ( Y ; a , σ )}{\partial {σ}^{2}} \vert σ = {σ}^{*} < 0 , \qquad ( 11 a )$$

Because the maximum-likelihood equation given by expression (8) is a transcendental equation, it cannot be inverted to solve directly for a*, whereas the solution of expression (11) for σ* is direct.

Bounds on the estimate of a and σ are obtained from the variance of the score function, also called the Fisher information J, which is more conveniently expressed in terms of the derivatives of the score functions. Given the parameter θ^{T}=[a σ] and the score function s^{T}_{θ}(Y; θ)=[Sa(Y; a, σ) s_{σ}(Y; a, σ)], expression (11b) results:

$$J ( θ ) = - E ⌈ \frac{\partial {s}_{θ}^{T} ( Y ; θ )}{\partial θ} ⌉ \qquad ( 11 b )$$

From expressions (7), (9), and (11b); expression (11c) results as follows:

$$J ( θ ) = ( \begin{matrix}\frac{N ( n - 1 ) ( 2 N - 1 )}{3 {a}^{2}} & \frac{N ( N - 1 )}{a σ} \\ \frac{N ( N - 1 )}{a σ} & \frac{2 N}{ {σ}^{2}}\end{matrix} ) \qquad ( 11 c )$$

By the Crámer-Rao theorem, a lower bound on the variance of any unbiased estimator is J⁻¹(θ), which is given by expression (11d):

$${J}^{- 1} ( θ ) = ( \begin{matrix}\frac{6 {a}^{2}}{N ( {N}^{2} - 1 )} & - \frac{3 a σ}{N ( N + 1 )} \\ - \frac{3 a σ}{N ( N + 1 )} & \frac{{σ}^{2} ( 2 N - 1 )}{N ( N + 1 )}\end{matrix} ) \qquad ( 11 d )$$

From the asymptotic properties of maximum-likelihood estimators, the estimates of a and σ are asymptotically unbiased and their variances achieve the Crámer-Rao lower bound (i.e., they are efficient estimates). Thus, if a* and σ* are the estimates obtained from the solutions of expressions (8) and (11), the variance of the estimates are given by expressions (11e) and (11f) as follows:

$$E [ {( {a}^{*} - a )}^{2} ] \geq \frac{6 {a}^{2}}{N ( {N}^{2} - 1 )} \qquad ( 11 e )$$

$$E [ {( {σ}^{*} - σ )}^{2} ] \geq \frac{{σ}^{2} ( 2 N - 1 )}{N ( N + 1 )} \qquad ( 11 f )$$

with equality being achieved in the limit of large N. As the variance of a and σ are of order O(N⁻³) and O(N⁻¹), respectively, the estimation error can be made arbitrarily small if observation windows are made sufficiently large.

Given an estimation window length and the sequence of observations y(n) in the window, the zero of the score function expression (8) provides an estimate of a. The function is a transcendental equation that can be solved numerically by iteration. However, the estimate of σ can be obtained directly from expression (11). A two-step procedure was followed: (1) an approximate solution for a* from expression (8) was obtained, and (2) the value of σ* was updated from expression (11). The procedure was repeated, providing successively better approximations to a* and σ*, and so converging on the root of expression (8).

Referring to FIG. 2, one embodiment of RT estimation is illustrated in flowchart form as procedure 120. Procedure 120 can be implemented with system 20 in accordance with operating logic of processor 32. Procedure 120 begins with operation 122. In operation 122, window counter k is initialized to one (k=1). Counter k indexes to a series of time-based windows for RT estimation. Procedure 120 continues with operation 124. In operation 124, “N” number of sound samples (observations) are taken over the current RT estimation window indexed with counter k. As previously explained, window length (duration) can be selected to bear on the relative degree of estimation error.

In one preferred embodiment, window length is set to be at least one τ in duration, provided that the window does not span multiple segments by bridging sound gaps to an undesirable degree. Alternatively, if gaps between sound segments are relatively short, then increasing the window length beyond the mean gap can produce undesirable effects where the next sound segment creeps into the window. Accordingly, in another preferred form, window length is selected to be greater than about one-half τ and less than the mean duration of anticipated gaps. Nonetheless, in other embodiments, different window length selection criteria can be utilized, if any. In still other embodiments, window length is adaptive—being changed automatically based on observed results, and/or is manually adjustable.

From operation 124, procedure 120 proceeds to maximum likelihood estimator routine 130. Referring to FIG. 3, further details of routine 130 are shown in flowchart form. In operation 132 of routine 130, an initial estimate a* is made. In operation 134, this initial estimate is utilized in expression (11) to calculate the corresponding σ* parameter estimate pair. From operation 134, conditional 136 is executed, which tests whether a desired degree of convergence has been obtained for the (a*, σ*) parameter estimate pair. If the test of conditional 136 is negative (false), operation 138 is performed which updates the a* estimate using expression (8). Routine 130 then loops back, returning to operation 134 to revise the estimate of σ* with the updated value a* from operation 138. Execution of this loop from operation 134 through operation 138 continues until the convergence test of conditional 136 is satisfied. Once the test of conditional 136 is positive (true), routine 130 returns a* and σ* as the estimator parameters in operation 140.

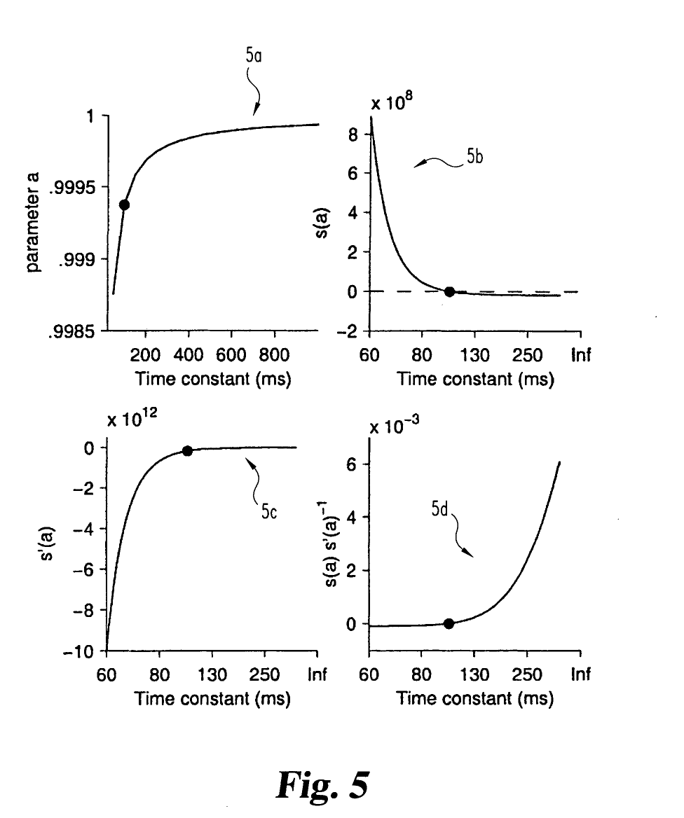

In some implementations, it is generally desired that these parameters be determined in the smallest number of iterations possible. Turning to FIG. 5, various aspects of maximum likelihood estimation are considered with respect to iteration minimization. More specifically, FIG. 5 illustrates various aspects of the Maximum-Likelihood Estimation (NLE) of room decay rate. Plot 5a of FIG. 5 maps the decay rate of the exponential decay (τ, abscissa) to parameter a=exp(−1/τ) (ordinate). This function is monotone, and maps τε[0, ∞) onto a ε[0,1). The filled circle shows τ=100 ms (a=0.9994). Plot 5b of FIG. 5 shows that the score function, sₐ(a), (derivative of log-likelihood function) as the ordinate, which decreases rapidly as a function of a (abscissa), marked in time constants using the map in plot 5a. MLE of a is given by the root of sₐ (filled circle). In plot 5c of FIG. 5, the derivative sₐ′(a) as a function of a is shown at the root of sₐ (filled circle), which is negative. For this example, about 8-12 orders of magnitude occur in sₐ and sₐ′for commonly encountered values of τ. In plot 5d of FIG. 5, the ratio sₐ(a)/sₐ′(a) (ordinate) as a function of a is the incremental step size of the Newton-Raphson procedure for finding the root of expression (8). It provides an estimate of the convergence properties of the root-finding algorithm. The sampling frequency for FIG. 5 plots was 16 kHz, and the log-likelihood function was calculated with a 400 ms window.

It should be understood that generally the geometric ratio is highly compressive and values of a for real environments are likely to be close to 1. Thus, it is often more desirable to estimate a rather than τ due to the more bounded nature of a. The score function sₐ from expression (7), on the other hand, has a wide range (about 8 orders of magnitude, see plot 5b), and is zero at the room decay rate (filled circle). The gradient of the score function dsₐ/da shown in plot 5c also demonstrates a wide range, but takes a negative value at the zero of sₐ.

Thus, starting with an initial value of a*<a, it is generally desirable that the root-solving strategy descend the gradient in a rapid manner. One technique for solving this kind of nonlinear equation, where an explicit form for the gradient is available, is the Newton-Raphson approach which offers second-order convergence. The order of convergence can be assessed from sₐ(dsₐ/da)⁻¹ which is the incremental step size Δa in the iterative procedure (see plot 5a of FIG. 5). For example, with a true value of τ=100 ms, Δa at intermediate values in the iteration can be as small as 10⁻⁶ when a=0.9993 (τ=90 ms) or a=0.9995 (τ=120 ms). This appro corresponds to an incremental improvement of about 0.01 ms for every iteration, thus providing slow convergence if the initial value is far from zero. On the other hand, the bisection method provides rapid gradient descent, with less desirable performance where the gradient changes relatively slowly (such as near the true value of a). The specific structure of the root-solving problem can be exploited because the behavior of sₐ is known. Accordingly, in one form of routine 130, a combination of both approaches can be utilized. In one such example, the root was bisected until the zero was bracketed, after which the Newton-Raphson method was applied to polish the root. For the example shown, the root bracketing was accomplished in about 8 steps and the root polishing in 2-4 steps. In contrast, with the same initial conditions, the Newton-Raphson method took about 500 steps to converge.

Referring back to FIG. 2, routine 130 returns with the parameters to estimate RT for the current window, as indexed by k. From routine 130, procedure 120 continues with conditional 150. Conditional 150 tests whether enough windows (total quantity “k”) have been evaluated, providing a corresponding number of RT estimates. If the test of conditional 150 is negative (false), procedure 120 continues with conditional 154. Conditional 154 tests whether to continue procedure 120. If the test of conditional 154 is positive (true), procedure 120 continues with operation 156 with increments k by 1 (k=k+1), to point to the next time-based RT estimation window of “N” sound samples. Correspondingly, from operation 156, procedure 120 loops back to operation 124, and subsequently routine 130 for re-execution. Conditional 150 is then again encountered. Provided conditional 150 remains negative and conditional 154 remains positive, k number of RT estimates are established. These RT estimates are each calculated from a different window and correspond to a different sequence of N sound observations. While different, each window can include one or more samples from one or more other windows. In one arrangement, each successive window overlaps many of the samples of the immediately previous window—and may differ by only one sample in a particular embodiment. For instance, advancement from one window to the next may occur with each new sample, displacing only the oldest sample with each advancement. On the other hand, in alternative embodiments, all the samples may be different from one window to the next, with or without uniform temporal separation between successive windows.

Once the test of conditional 150 is positive (true), operation 153 is executed. By advancing the frame (window) as the signal evolves in time, a series of estimates a*ₖ will be obtained. Some of these estimates will be obtained during a free decay following the offset of a sound segment (“good” estimations), whereas some will be obtained when the sound is ongoing (“poor” estimations). Thus, a strategy is required for selecting only those estimates that correctly represent regions of free-decay and hence the real room decay rate. This approach requires a decision-making strategy that examines the distribution of the estimates after a sufficient number of windows have been processed, and makes a decision regarding the true value of the room decay rate.

For a blind estimation procedure of this type the input is unknown, and so the model is inapplicable to: (1) an estimate obtained in a frame that is not occurring during a free decay (includes regions where there is sound onset or sound is ongoing—the MLE scheme can provide widely fluctuating or implausible estimates as a result); or (2) during a region of free decay initiated by a sound with a gradual rather than rapid offset, in which case the offset decay of the sound will be convolved with the room response, such convolution prolongs the sound even further and so, the estimated decay rate will be larger than the real room decay rate.

Notably, where the estimation frames do not fall within a region of free decay, many of the time frames will provide estimates of a close to unity (i.e., infinite τ), or otherwise implausible values. On the other hand, the estimates will accurately track the true value when a free decay occurs. One strategy for selecting a from the sequence a*ₖ is guided by the following observation: the damping of sound in a room cannot occur at a ratefaster than the free decay, and thus all estimates a* must attain the true value of a as a lower bound. This lower bound is achieved when a sound terminates relatively abruptly—for which the model conditions will be better satisfied with the estimator providing a better representation of the true value of the decay rate.

It should be recognized that even during a free decay the estimate is inherently variable (due to the underlying stochastic process), and so selecting the minimum, (a=min (a*ₖ)), may underestimate a. One robust strategy selects a threshold value of a* such that the left tail of the probability density function of a*,p(a*), occupies a pre-specified percentile value γ. This approach can be implemented using an order-statistics filter specified by expression (12) as follows:

$$a = arg \{ P ( x ) = γ \text{:} P ( x ) = {\int }_{0}^{x} p ( {a}^{*} ) ⅆ {a}^{*} \} \qquad ( 12 )$$

For a unimodal symmetric distribution with γ=0.5 the filter will track the peak value, i.e., the median. It should be noted that for γ values approaching 0, the filter of expression (12) approaches the minimum filter a=min{a*ₖ} suggested above.

In the second case described above, where the sound offset is gradual, p(a*) is likely to be multimodal because sound offsets (such as terminating phonemes in speech) will have varying rates of decay, and their presence will give rise to multiple peaks. The strategy then is to select the first dominant peak in p(a*) when a* is increasing from zero (i.e., left most peak). That is given by expression (13) as follows:

a=min arg{dp(a*)/da*=0}, (13)

where the minimum is taken over all zeros of the equation. If the histogram is unimodal but asymmetric, the filter tracks the mode and resembles the order-statistics filter.

Returning to FIG. 2, operation 152 filters the accumulated RT estimates for each of k windows. These estimates are designated as the aₖ estimation series. The filtering outputs a desired RT estimate believed to be most desirable for the k windows evaluated. In one form, a filter is applied in accordance with expression (12) and/or (13). In connected speech, where peaks cannot be clearly discriminated or the distribution is multimodal, expression (12) can be employed by choosing a value of γ based on the statistics of gap durations. For instance, if gaps constitute approximately 10% of total duration, then γ=0.1 would be a reasonable choice. A judicious choice of γ can result in the filter performing like an edge detector, because it captures the transition from larger to smaller values of the time-evolving sequence a*ₖ.

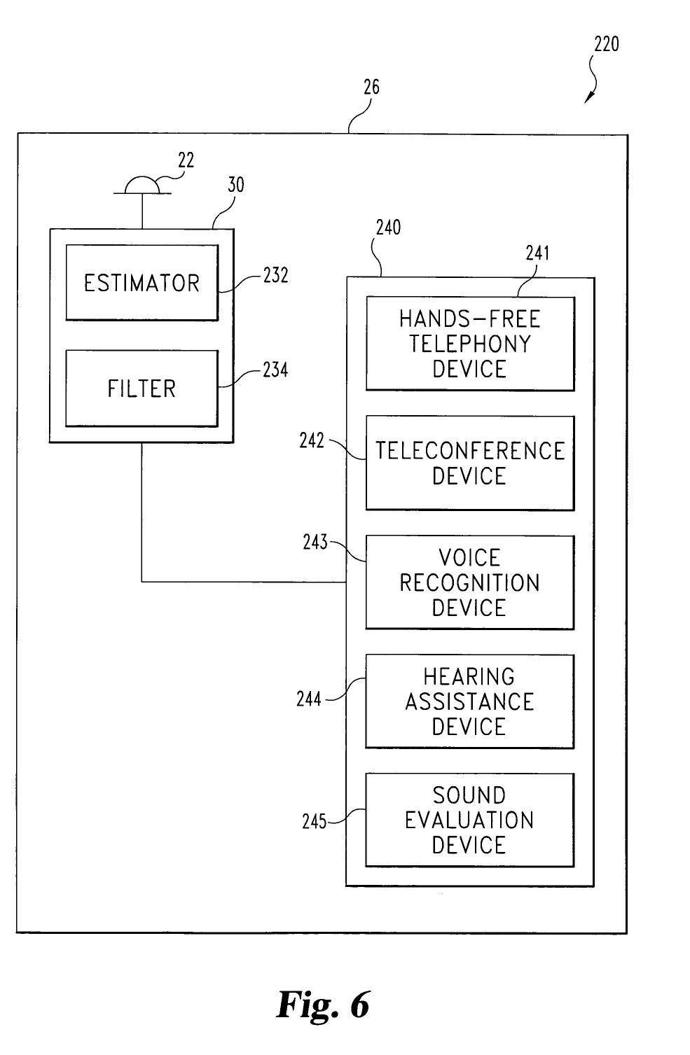

Operation 152 can output an RT estimate to be used in any of a variety of further processing routines with device(s) 40. FIG. 6 schematically represents a few of these implementations, which is further described hereinafter. From operation 152, procedure 120 encounters operation 153, which resets counter k to one (k=1). From operation 153, procedure 120 continues with conditional 154, which tests whether to continue RT estimation. If so, then the affirmative branch of conditional 154 is followed to operation 156 to increment k and RT evaluation. If the test of conditional 154 is negative, procedure 120 halts. It should be appreciated that the value for N samples used in operation 124, the initial estimate of a* in operation 132, the selection minimum of conditional 150, and/or one or more aspects of the filter in operation 152 (such as 8), can be arranged to be operator adjustable, and/or automatically adjusted by an adaptive processing routine or the like.

FIG. 6 depicts arrangement 220 of various applications of RT estimation according to procedure 120; where like reference numerals refer to like features previously described in connection with system 20. Arrangement 220 includes sensor 22 operatively coupled to processing subsystem 30 in room 26. Subsystem 30 includes parameter estimator 232 and filter 234. Parameter estimator 232 is of the NLE type described in connection with routine 130. Additionally or alternatively, in other embodiments a different type of parameter estimator can be included, such as a Bayesian, mean-square, and/or minimax type, just to name a few. It should be appreciated that the NLE estimator of procedure 120 is implemented in procedure 120 to generally provide robust estimation; where “robust estimation” refers to an estimation scheme that optimizes the performance to the least favorable statistical environment among a specified statistical class.

Parameter estimator 232 is utilized in accordance with procedure 120 to provide a number of RT estimates that are input to filter 234. Filter 234 is of a type that performs in accordance with expressions (12) and/or (13) as previously described in connection with procedure 120. Filter 234 provides an RT estimation output that is provided to devices 240 of arrangement 220. Devices 240 embody a number of different examples of RT applications, including hands-free telephony device 241, teleconference/telepresence device 242, voice recognition device 243, hearing assistance device 244, and sound evaluation device 245. Each of devices 240 utilizes RT estimates in a corresponding telephony, teleconference/telepresence, hearing assistance, or sound evaluation data processing routine, respectively. Such routines can be executed, at least in part, with subsystem 30 and/or the corresponding device 240. While shown together for convenience of illustration, it should be understood that an alternative embodiment includes only one of devices 240 integrated with subsystem 30 and/or sensor 22—providing an application-specific implementation of RT estimation according to the present invention. One example of this type is a multimode hearing aid. Programmable hearing aids often have the ability to switch between several processing schemes depending on the listening environment. For instance, in highly diffusive environments, where the source-to-listener distance exceeds the critical distance, adaptive beamformers are ineffective. In such situations, it would be convenient to switch off the adaptive algorithm and revert to the relatively simple (fixed) delay-and-sum beamformer. Alternatively, in highly-confined listening environments such as automobile interiors, where a reflecting surface is located in close proximity to the ear, it may be convenient to switch-off the proximal ear microphone, and use the input from the microphone located in the better (more distal) ear. Such decisions can be made if there is a passive technique for determining reverberation characteristics. In other embodiments, one or more of the other device types shown may not be utilized and/or utilized in different quantity. Alternatively or additionally, one or more of devices 240 can be combined with one or more other of devices 240.

The blind estimation procedure suggested can be applied in a number of situations. Because only passive sounds are used, any audio processor that has access to microphone input can estimate the room reverberation time, either in single channel (broadband) or multichannel (narrowband) mode. Further, while implemented with a single sensor or microphone, the present invention can be implemented with two or more sensors/microphones or a larger array of microphones, providing several independent estimates of the RT. With respect to frequency, it has been observed that RT estimation according to the present invention is particularly desirable for broadband signals and narrowband signals with a center frequency that exceeds 1 kHz.

### Experimental Results

To investigate the MLE method, sound recordings were made in several rooms, building corridors and an auditorium, with the aim of determining their reverberation times. Sound stimuli that were used included 18-tap maximum length sequences (period length of 2¹⁸−1), clicks (100 μs), hand-claps, word utterances, and connected speech from the Connected Speech Test (CST) corpus. Recordings were made using a Sennheiser MK-II omnidirectional microphone (frequency response 100-20000 Hz). Microphone cables (Sennheiser KA 100 S-60) were connected to the XLR input of a portable PC-based sound recording device (Sound Devices USBPre 1.5). The recorder transmitted data sampled at 44.1 kHz to a laptop computer (Compaq Presario 1700, running MicrosoftWindows XP) via a USB link. The sound stimuli, stored as single-channel presampled (44.1 kHz) WAV files, were played through the headphone output of the laptop, amplified by a power amplifier (ADCOM GFA-53511) and presented through a loudspeaker (Analog and Digital Systems Inc., ADS L200e). Data acquisition and test material playback were controlled by a custom-written script in MATLAB (The MathWorks Inc.) using the Sound PC Toolbox (Torsten Marquardt).

Experimentally recorded data from real listening environments were processed using the MLE procedure and compared to results obtained from the Schroeder procedure. Experimentally, RT is determined from decay curves obtained by radiating sound into the test enclosure. The sound source is switched on, and when the received sound level reaches a steady state, it is switched off. The decay curve is the received signal following the cessation of the sound source, according to the Interrupted Noise Method (ISO 3382, 1997). When the excitation signal is a noise source, the decay curve will be different from trial-to-trial due to random fluctuations in the signal, even when the experimental conditions are unchanged. This fluctuation is due in part to the random phase and amplitudes of the normal modes at the moment the excitation signal is turned off. Before performance of Schroeder's procedure, fluctuations in RT estimates were minimized by averaging the RTs obtained from many decay curves. Schroeder developed an alternate method that in a single measurement, yields the average decay curve of infinitely many interrupted noise experiments, which eliminates the averaging procedure.

Following Schroeder, let n(t) be a stationary white noise source with power σ² per unit frequency, and τ(t) be the impulse response of the system consisting of the receiver, transmitter, and the enclosure. Then a single realization of the decay curve s(t) from the interrupted noise experiment is given by expression (14) as follows:

$$s ( t ) = {\int }_{- ∞}^{0} n ( τ ) r ( t - τ ) ⅆ τ \qquad ( 14 )$$

where the noise is assumed to be switched off at t=0, and the lower limit is meant to signify that sufficient time elapsed for the sound level to reach a steady state in the enclosure before it was switched off. The reverberation time is obtained from the decay curve s(t) (see below).

In practice, the experiment was repeated to obtain a large number of decay curves, and RTs from these curves were averaged. Schroeder used expression (14) to establish a relationship between the mean squared average of the decay curve s(t) and the impulse response of the enclosure τ(t), namely given by expression (15) as follows:

$$E [ {s}^{2} ( t ) ] = {σ}^{2} {\int }_{0}^{∞} {r}^{2} ( τ ) ⅆ τ \qquad ( 15 )$$

While the ensemble average on the left-hand side of expression (15) requires averaging over many trials, the right-hand side of expression (15) requires only a single measurement, as it is the impulse response of the enclosure plus receiver and transmitter.

Schroeder's procedure, often called the Integrated Impulse Response Method (or sometimes, Backward Integration Method), can be applied to a single broadband channel (such as an impulsive sound covering a broad range of frequencies) or to a narrowband channel consisting of a filtered impulse (such as a pistol shot). The only requirement is that the power spectrum of the excitation signal (right-side of expression (15)) should be identical to the power spectrum of the noise burst (in the noise decay method, left-side of expression (15)).

The recorded data were filtered offline in ISO one-third octave bands (21 bands with center frequencies ranging from 100-10000 Hz) using a fourth-order Type II Chebyshev band-pass filter with stopband ripple 20 dB down. The output from each channel was processed by procedure 120 and Schroeder's procedure using expression (15). For broadband estimation, the microphone output was processed directly using both approaches.

Due to the limited dynamic range of sounds in real environments, Schroeder's method requires the specification of a decay range. The decay ranges normally used are from −5 dB to −25 dB (20 dB range), and from −5 dB to −35 dB (30 dB range). The decay curves in each range were fitted to a regression line using a nonlinear least squares fitting function (function “nonlinsq” provided by MATLAB). The fitted function was of the form Aa_{d}ⁿ, where A is a constant, n is the sample number within the decay window, and a_{d} is the geometric ratio related to the decay rate τ_{d} of the integrated impulse response curve by a_{d}=exp(−1/τd). This approach is in contrast to the model depicted in expression (2) which assumes an exponentially decaying envelope with decay rate τ, whereas Schroeder's decay curve is obtained by squaring the signal. Hence, τ_{d}=τ/2. Two estimates of the decay rate were obtained from decay curves fitted to the −5 to −25 dB, and −5 to −35 dB drop-offs. For each fit, the line was extrapolated to obtain T₆₀ time (in seconds) using expression (16) that follows:

$${T}_{60} = \frac{6}{{log}_{10} ( {ⅇ}^{- 1} ) {log}_{e} ( {a}_{d} )} = \frac{- 6 {τ}_{d}}{{log}_{10} ( {ⅇ}^{- 1} )} = 13.82 {τ}_{d} \qquad ( 16 )$$

The same procedure was followed for determining the decay rate from broadband signals. It should be noted that the MLE procedure does not require the specification of a decay range, but only the specification of the estimation window length; thus, only one estimate per band is obtained.

Microphone data were processed using the MLE procedure to obtain a running estimate of the decay rate. For model verification, estimation was performed on: 1) the segment following the cessation of a maximum-length sequence or a hand-clap, and 2) the entire run of a string of isolated word utterances. These were considered desirable stimuli, because they fulfilled the model assumptions of free decay or possessed long gaps between sound segments. The estimates were binned for each run and a histogram was produced. The histogram was examined for peaks, and the decay rate was selected using the order-statistics filter expression (13) if there were multiple peaks, or expression (12) if the histogram was unimodal. The estimate â so obtained was used to calculate T₆₀ (in seconds) using expression (17) as follows:

$${T}_{60} = \frac{3}{{log}_{10} ( {ⅇ}^{- 1} ) {log}_{e} ( \hat{a} )} = \frac{- 3 τ}{{log}_{10} ( {ⅇ}^{- 1} )} = 6.91 τ \qquad ( 17 )$$

The T₆₀ relationships given by expressions (16) and (17) are approximately the same due to the relationship between τ and τ_{d}, with any difference being ascribed to model differences and/or discrepancies in measurement and analysis.

The performance of the MLE was also evaluated using connected speech played back in a circular building foyer (6 m diameter). Test materials were connected sentences from the CST corpus. Estimates from nonoverlapping 1 second intervals were binned to yield a histogram, and the first dominant peak from the left of the histogram was selected to determine the room decay rate. The procedure for calculating T₆₀ time followed expression (17).

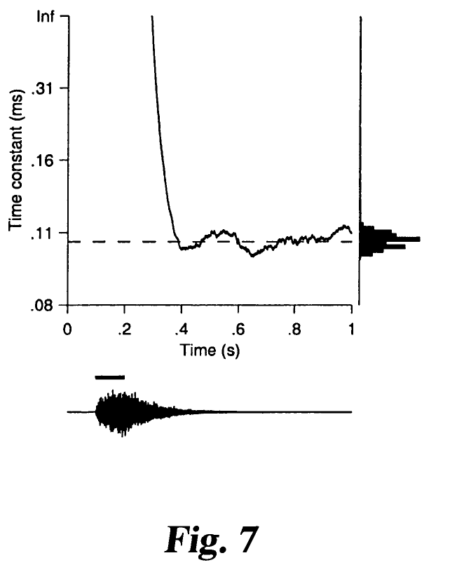

The estimation procedure was applied to a variety of data sets, including simulated data and real room responses. To illustrate the techniques involved, simulated data sets are considered next. FIG. 7 provides an illustration of a procedure for continuous estimation of decay rate. A burst of white noise (8 kHz bandwidth) was convolved with the impulse response of a simulated room having a decay rate of τ=100 ms. The noise burst was applied at time t=0.1 s (black bar, bottom trace, 100 ms duration). A simulated room output (bottom trace) shows the build-up and decay of sound in the room. A running estimate of the parameter a in 200 ms windows is shown in the graph (ordinate, a converted to decay rate in seconds). The true value of decay rate (100 ms) is shown as a horizontal dashed line. The estimation window was advanced by one sample to obtain the trace, with each point at time t being the estimate in the window (t-0.2, t). During the build-up and ongoing phase of the sound (time frames up to about t=0.3 s) estimated a sometimes exceeded one (i.e., negative values of τ). These were discarded so that all values of a were bounded to be less than one (if a<1). As the window moved into the region of sound decay (t>0.3 s), the estimates converged. A histogram of the estimated decay rate is sown to the right of the trace. An order-statistics filter was utilized with gamma (γ)=0.5 to extract the room decay rate of τ=101 ms. The sampling rate was 16 kHz.

For comparison, the procedure was repeated with the simulated noise burst input before it was convolved with the room impulse response to mimic anechoic conditions. The histogram demonstrated a strong peak at a=1 (τ=∞) (not shown), which showed that in the absence of reverberation, as in an anechoic environment or open space, histograms showing strong peaks at a=1 are to be expected.

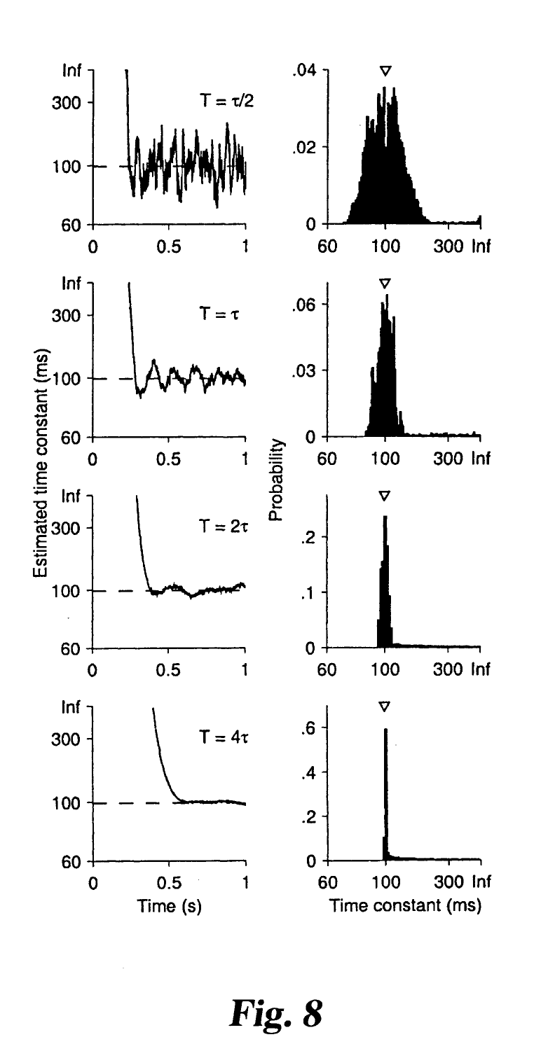

Estimation performance varies with window length N specified in expression (8). To demonstrate the effect of window length a burst of white noise (100 ms duration) was convolved with a simulated room impulse response (τ=100 ms), and the estimator tracked the decay curve using four different window lengths as shown in the four comparative pairs (rows) of graphs of FIG. 8. In FIG. 8, the simulation shown in FIG. 7 was repeated for windows of duration 0.5τ, τ, 2τ, 4τ(top to bottom), where τ=100 ms is the true value of the room decay rate. The left column shows the running estimate of parameter a (ordinate, shown as decay rate in ms) as a function of time (abscissa). The right column shows the corresponding histogram of the estimates. The variance of the estimate decreases with increasing window length (arrowheads mark value of τ). As window length increased from 0.5τ to 4τ, the MLE procedure gave improved estimates. As illustrated in these examples, increasing window length reduces variability in the estimates, without introducing significant bias.

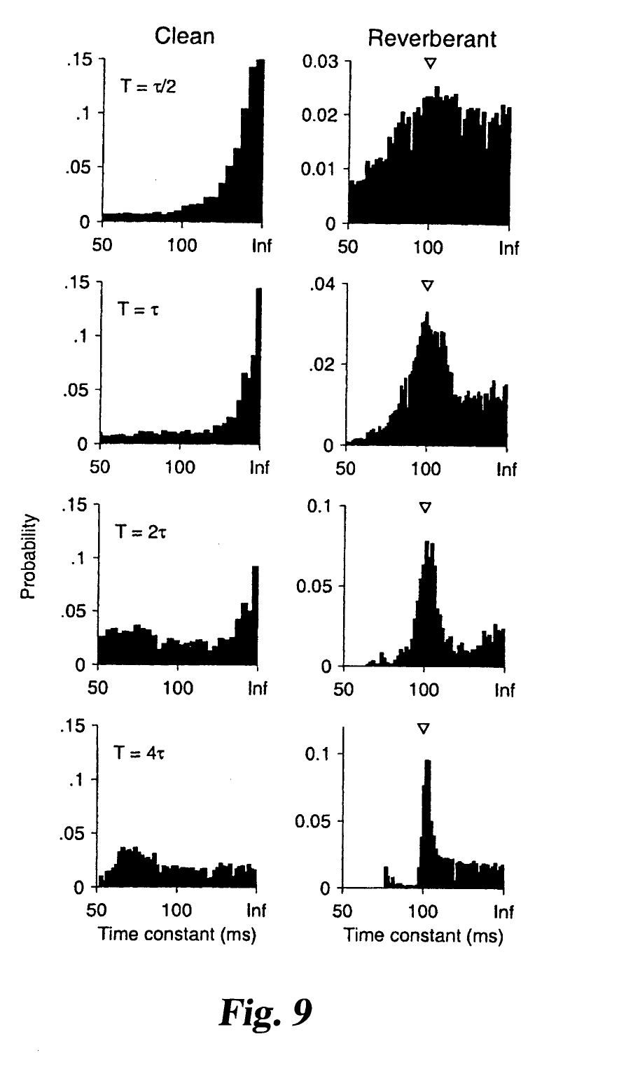

In other examples, a sequence of 15 distinct and isolated American-English words were recorded in an anechoic environment at a sampling rate of 20 kHz. These included eleven consonant-vowel-consonant words (/p,b,g/V/d/, e.g., “bed”), and four consonant-vowel words (/b/V/, e.g., “bay”) separated by a mean interval of 200 ms which were convolved with a simulated room impulse response having a decay rate τ=100 ms. The estimator tracked the decays for the entire duration of the sequence (approximately 11.4 s). The control condition was the clean input (i.e., anechoic). FIG. 9 illustrates experiments for this estimation of room decay rate from speech using the four window lengths described in connection with FIG. 8. Histograms of decay rates were estimated from clean (left column) and simulated reverberant responses (right column), and are shown for window durations 0.5τ, τ, 2τ, and 4τ(four corresponding rows, top to bottom). The histogram for “clean” speech served as a control. Estimation from reverberant speech produces a clearly defined peak, especially for the longer window lengths, with a small bias (right column, 2τ and 4τ), that can be attributed to the gradually decaying offsets inherent in speech—such that the resultant decay is speech offset convolved with the room response. For the control condition (left column) the offset decay is visible only in the bottom two rows where the histogram exhibits a broad bump between 50 and 100 ms. This can also be seen in the “anechoic” control condition where a small peak is noticeable when window size is 4τ(bottom panel, left column). The peak occurs at about 60 ms, and corresponds to the gradual offsets of speech sounds.

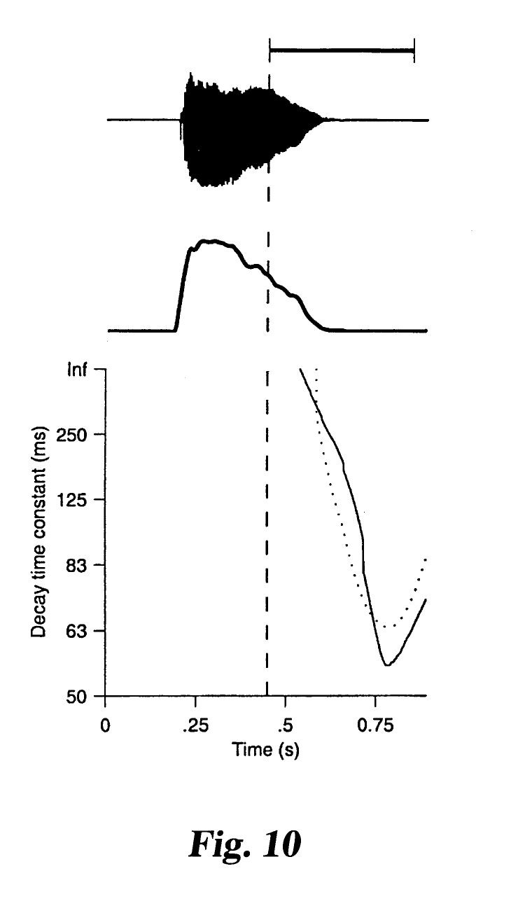

Next, performance of the estimator of the present invention is considered in greater detail with the input consisting of a single word “bough” (/b/V/). The word was recorded under anechoic conditions and presented to the estimator without modification so that the effect of the vowel offset could be determined. The results are shown in FIG. 10. The terminating vowel has a gradually decaying offset (top panel). Estimation of the offset decay was performed from t=0.45 s (vertical dashed line) using two procedures. First, the envelope was extracted from the analytic signal via a Hilbert transform, windowed, and filtered to eliminate frequency components above 100 Hz. The envelope is shown in the middle panel (heavy outline). The envelope was then squared and transformed to a decibel scale, and the decay rate was estimated in windows of duration 0.4 s (horizontal bar), using a least squares fit to a straight line. Successive estimates were obtained from overlapping segments by sliding the window forward with a one sample step size. Note that the time at which an estimate is reported for any given window is the end point of the window. The estimate for the window indicated by the horizontal bar, for instance, is plotted at time t=0.85 s. A curve of the estimated decay rates was thus obtained (dotted curve, bottom panel). The MLE procedure was applied to the same segments and produced an independent estimate of the decay rate (solid line, bottom panel). The estimates are in qualitative agreement. Both procedures indicate that the terminating vowel had a time-dependent decay rate, and the greatest rate was between 50 and 70 ms.

The results confirm the presence of the peak in FIG. 9 (left column, bottom panel), although the histogram shown in FIG. 9 was obtained for a sequence of 15 words. Taken together, the results from FIGS. 8-10 suggest that estimation can be influenced by the presence of adequate numbers of gaps, sharp offset transients, and estimation window length.

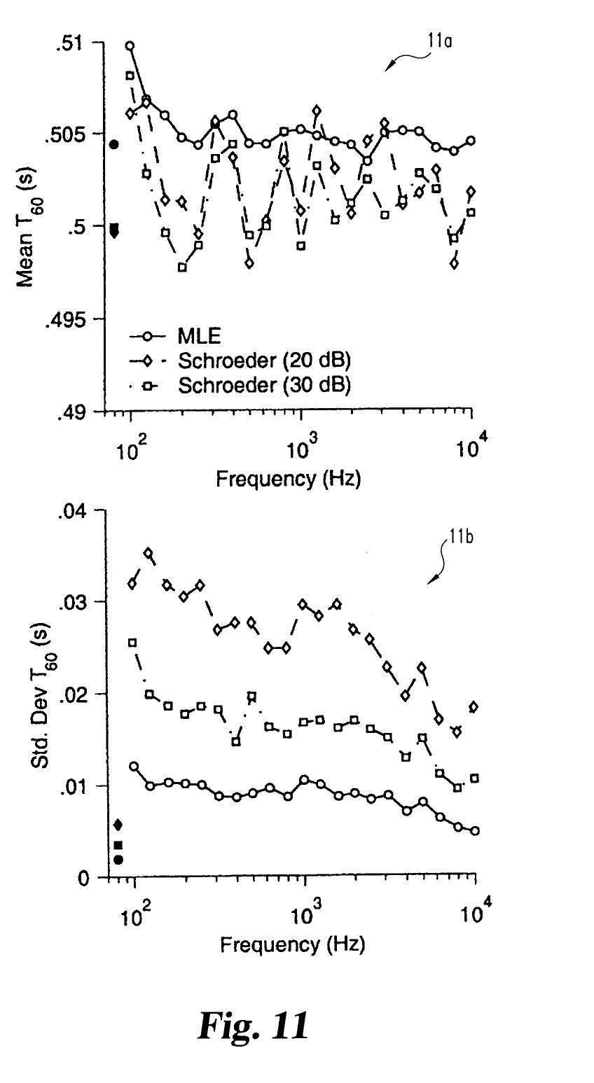

The MLE estimates were compared to the procedure by Schroeder in both single-channel (i.e., the broadband signal), and multichannel frameworks (i.e., narrowband signals occupying one-third octave bands). While Schroeder's procedure requires a fitting procedure to estimate the decay rate in a preselected decay range (either 20 or 30 dB below a reference level of −5 dB), the MLE procedure does not require the specification of such a range. To determine whether the two methods provide comparable RT values, estimations were performed on a simulated room decay curve with RT=0.5 s as illustrated in FIG. 11. Broadband and one-third octave band estimates were obtained using the MLE method (circle) and Schroeder's procedure (20 dB: lozenge, 30 dB: square). Plot 11a of FIG. 11 shows the mean value of RT as a function of center frequency of the one-third octave bands (open symbols) and the broadband estimate (filled symbols near y axis range) averaged over 100 trials. The broadband estimates were 0.504 s (MLE), and 0.5 s (Schroeder) for both the 20 and 30 dB decay ranges. The discrepancy was less than 1%. The one-third band MLE estimates differed from the Schroeder estimates by no more than about 0.5% (mean RT over all bands were, MLE: 0.505, Schroeder's method: 0.502 s for 20 dB and 0.501 s for 30 dB). Plot 11b of FIG. 11 provides a comparison of standard deviation. The MLE procedure demonstrated lower standard deviation (SD) across trials than Schroeder's procedure, by a factor of 2 (for the 20 dB curve) and 3 (for the 30 dB curve). Further, NLE estimates were similar across one-third octave bands at frequencies above 200 Hz, (plot 11a), whereas estimates from Schroeder's procedure exhibited greater variability. The results establish that the MLE procedure and Schroeder's procedure are in good agreement.

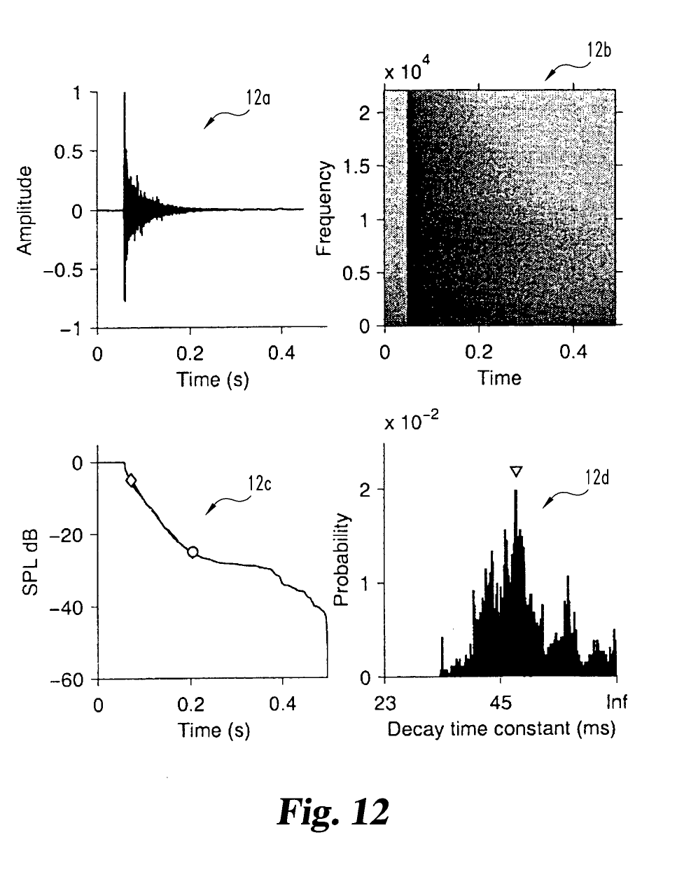

Comparisons are also made using a hand-clap in a small office (8×3×3 m), and for results obtained in rooms of different sizes. FIG. 12 provides plots 12a-12d corresponding to estimation of decay rate from real room data. In plot 12a, the room response to a hand-clap is shown (same as plot 4a of FIG. 4 but also includes the direct sound). In plot 12b, a spectrogram of the hand-clap demonstrates a sharp broadband onset transient and the decay as a function of frequency. In plot 12c, decay rate was estimated using Shroeder's backward impulse integration method in the −5 dB (lozenge) to −25 dB (circle) range, followed by a least-squares fit to a straight line to obtain the decay rate (τ=56 ms, T₆₀=0.39 s), with normalization so that peak SPL was at 0 dB. In plot 12d, a histogram of decay rate was obtained from the signal shown in plot 12a using MLE. The median value of the histogram (arrow) is τ=53 ms, T₆₀=0.37. The RMS noise level in the room was 50 dBA SPL, and the peak sound pressure level resulting from the hand-clap was 85 dBA SPL. Plot 12c shows the broadband curve obtained by integrating the recorded microphone signal. A straight-line fit to the 20 dB drop-off point (circle) from a reference level of −5 dB (lozenge) yielded τ=56 ms (T₆₀=0.39 s). The discrepancy between this value and that presented in FIG. 4 (τ=59 ms) was due to the inclusion of the direct sound in FIG. 12. The windows over which the 20 dB drop-off was computed were not identical for the two cases. The data were run through the MLE procedure and a histogram of estimates was obtained, and the decay rate was calculated from the peak of the histogram using expression (12), which provided an estimate of τ=53 ms (T₆₀=0.37 s). This estimate is in good agreement with the estimate obtained using Schroeder's procedure.

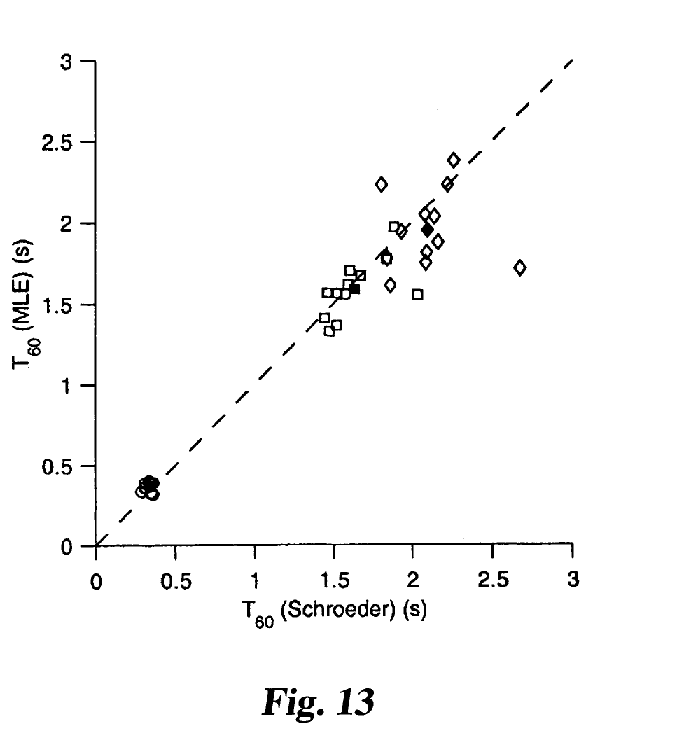

FIG. 13 illustrates T₆₀ estimates comparing MLE and Schroeder techniques for one-third octave band analysis (exceeding 1 kHz center frequency) in three environments. These environments were: (1) the moderately reverberant room for FIG. 12 (circles), (2) a highly reverberant circular foyer (squares), and (3) a highly reverberant enclosed cafeteria (diamonds). In all cases, the signal was a hand-clap generated at a distance of 2 m from the recording microphone (peak value 90 dB SPL). Output from the bandpass filters were analyzed using the MLE procedure, and the r value for each band was obtained from the histogram by selecting the dominant peak. For Schroeder's procedure, a 20 dB decay range was used. In FIG. 13, the ordinate shows the best estimates obtained from the NLE procedure for each band, and the abscissa shows the T₆₀ times obtained from Schroeder's method. Averages over all bands for each environment are shown as filled symbols. The diagonal dashed line (with unity slope) is shown for reference, with the distance from this line indicating a measure of agreement between the two procedures.

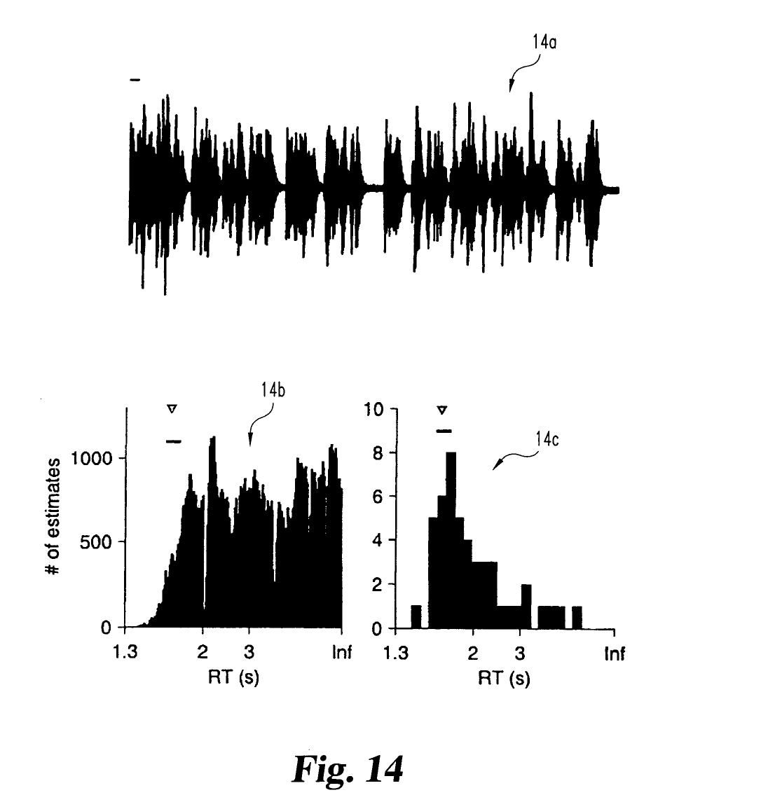

FIG. 14 depicts information from the evaluation of room reverberation (RT) from connected speech played back in a partially open circular foyer. The RT for this environment as measured from hand-claps was 1.66±0.07 s (Schroeder's procedure) and 1.62 s (from MLE procedure). Plot 14a provides a trace of CST passage (duration 50 s) recorded in the environment. The horizontal bar of plot 14a indicates 1 second (s). Plot 14b provides a histogram of MLE estimates over the duration of recording. The first peak in the aggregate histogram is the best RT estimate from connected speech (1.83 s). The horizontal bar is the range of RT estimates obtained from Schroeder's procedure, and the triangle indicates the MLE estimate. In plot 14c, peak values were obtained every second, and the 50 peak values were used to produce the histogram shown. The best estimate of RT from this histogram is at the dominant peak (1.7 s).

Filtering was used to select the first dominant peak in the histogram (RT=1.83 s). This is the best RT estimate based on the aggregate data. It is possible to refine the procedure for arriving at the best estimate by applying the filter at much shorter time intervals. Towards this end, the histogram of plot 14c was constructed at intervals of 1 s, and the best RT estimate for this interval was obtained. It can be seen that the number of estimate peaks at RT=1.7 s agrees with the mean value of 1.66 s from Schroeder's method (using hand-claps), and is within its standard deviation (0.07 s).

In a further form, the order-statistics filter is based on a statistical characterization of gap duration from a large corpus of connected speech or other sounds (to enhance RT estimate selection under certain circumstances). Such a characterization can provide a robust percentile cut-off value (see expression (12)) which could then be used to select the best RT value for the room.

Any theory, mechanism of operation, proof, or finding stated herein is meant to further enhance understanding of the present invention and is not intended to make the present invention in any way dependent upon such theory, mechanism of operation, proof, or finding. While the invention has been illustrated and described in detail in the figures and foregoing description, the same is to be considered as illustrative and not restrictive in character, it being understood that only selected embodiments have been shown and described and that all changes, modifications and equivalents that come within the spirit of the invention as defined herein or as follows are desired to be protected.

What is claimed is:

1. A method, comprising:
detecting sound with a sensor to generate a corresponding sensor signal;
generating data with the sensor signal in accordance with a maximum likelihood estimator; and
filtering the data with an order-statistics filter to provide an estimate of reverberation time.

2. The method of claim 1, which includes iteratively determining a decay time parameter and a power parameter during execution of said generating.

3. The method of claim 1, which includes providing the reverberation time to one or more of a hearing assistance data processing routine, a voice recognition data processing routine, a hands-free telephony data processing routine, a teleconference data processing routine, and a sound level evaluation data processing routine.

4. The method of claim 1, wherein said generating includes calculating a number of reverberation time parameter estimations with the maximum likelihood estimator, the estimations each being calculated as a function of a sequence of sound observations over a different time window.

5. A method, comprising:
detecting sound with a sensor to generate a corresponding sound signal;
iteratively determining two or more values with a maximum likelihood function to evaluate one or more reverberation characteristics of an acoustic environment, one of the values corresponding to a time-constant parameter and another of the values corresponding to a diffusive power parameter; and
providing an estimate corresponding to reverberation time of the acoustic environment.

6. The method of claim 5, wherein said iteratively determining is performed for each of a number of different frequency ranges of the sound and includes calculating a reverberation time estimate for each of the different frequency ranges.

7. The method of claim 5, which includes providing the estimate of reverberation time to one or more of a hearing assistance data processing routine, a voice recognition data processing routine, a hands-free telephony data processing routine, a teleconference data processing routine, and a sound level evaluation data processing routine.

8. The method of claim 5, wherein said iteratively determining is performed with each of a number of different data sequences to provide a number of reverberation time estimations, the data sequences each being representative of a series of sound observations over a different time window.

9. The method of claim 8, wherein said providing includes filtering the reverberation time estimations with an order-statistics filter to select the estimate corresponding to reverberation of the acoustic environment.

10. A method, comprising:
preparing a number of observed sound data sequences each representative of sound over one of a number of different time periods;
determining each of a number of estimations as function of a different one of the sequences in accordance with a maximum likelihood estimator; and
selecting one of the estimations to provide a reverberation time.

11. The method of claim 10, wherein said selecting includes filtering the estimations.

12. The method of claim 11, wherein said filtering is performed with an order-statistics filter.

13. The method of claim 10, wherein said determining includes iteratively calculating each of at least two values, a first one of the values corresponding to a decay time and a second one of the values corresponding to diffusive power.

14. The method of claim 13, wherein said iteratively calculating is performed for each of a number of different frequency ranges of the sound and includes calculating a reverberation time estimate for each of the different frequency ranges.

15. The method of claim 10, which includes providing the one of the estimations to one or more of a hearing assistance data processing routine, a voice recognition data processing routine, a hands-free telephony data processing routine, a teleconference data processing routine, and a sound level evaluation data processing routine.

16. The method of claim 10, wherein the sequences each correspond to a different series of observed sound samples and the different time periods each correspond to a different time window.

17. The method of claim 16, which includes adaptively changing the duration of the different time windows.

18. A method, comprising:
preparing a number of observed sound data sequences each corresponding to sound over a different one of a number of time windows;
determining a number of reverberation time parameter estimations, the estimations each being determined as a function of a different one of the sequences in accordance with a parameter estimator; and
filtering the estimations with an order-statistics filter.

19. The method of claim 18, wherein the parameter estimator is based on maximum likelihood estimation.

20. The method of claim 18, wherein the parameter estimator is of a robust type.

21. The method of claim 18, wherein said determining includes iteratively calculating each of at least two of the parameters for each of the sequences, a first one of the parameters corresponding to a decay time and a second one of the parameters corresponding to power.

22. The method of claim 21, wherein said iteratively calculating is performed for each of a number of different frequency ranges of the sound and includes calculating a reverberation time parameter estimate for each of the different frequency ranges.

23. The method of claim 18, which includes selecting one the estimations based on said filtering.

24. The method of claim 23, which includes providing the one of the estimations to one or more of a hearing assistance data processing routine, a voice recognition data processing routine, a hands-free telephony data processing routine, a teleconference data processing routine, and a sound level evaluation data processing routine.

25. The method of claim 18, which includes adaptively changing the duration of the time windows.

26. A system, comprising:
a sensor for detecting sound; and
a processing subsystem operable to receive sound-representative signals from the sensor to determine a reverberation time estimate of an unknown acoustic environment by processing the signals with a parameter estimator and order-statistics filter.

27. The system of claim 26, wherein the parameter estimator is of robust type.

28. The system of claim 26, wherein the parameter estimator is of a maximum likelihood type.

29. The system of claim 26, further comprising means for processing the reverberation time estimate in one or more of a hearing assistance data processing routine, a voice recognition data processing routine, a hands-free telephony data processing routine, a teleconference data processing routine, and a sound level evaluation data processing routine.

30. The system of claim 26, wherein the subsystem includes:
means for processing a number of sequences of observed sound data to provide a corresponding number of reverberation time parameter estimations with the parameter estimator, the sequences each corresponding to one of a number of different time windows; and
means for filtering the estimations with the order-statistics filter to provide the reverberation time estimate.

31. The system of claim 30, further comprising at least one of:
means for performing the processing means for each of a number of different frequency ranges of the sound; and
means for adaptively changing the duration of the time windows.

32. An apparatus, comprising: a device carrying logic executable by a processor to process data corresponding to a number of sequences of sound samples, the sequences each being representative of sound over a different time period, the logic being further operable to determine a number of reverberation time parameter estimations each as function of a different one of the sequences in accordance with a maximum likelihood estimator and filter the estimations to provide a selected reverberation time estimate.

33. The apparatus of claim 32, wherein the logic includes a number of software instructions and the device includes a computer-readable memory storing the software instructions.

34. The apparatus of claim 32, wherein the device includes one or more parts of a computer network and the logic is encoded in one or more signals by the device.

35. The apparatus of claim 32, wherein the logic is operable to filter the estimations with an order-statistics type of filter.
